(19) United States
(12) Patent Application Publication
(10) Pub. No.: US 2004/0154656 A1
(43) Pub. Date: Aug. 12, 2004

(54) Nuclear radiation fueled power cells

(75) Inventors: Harry T. Weaver, Sandia Park, NM (US); Stephen D. Hersee, Albuquerque, NM (US); Steven R.J. Brueck, Albuquerque, NM (US)

Correspondence Address: GIBBONS, DEL DEO, DOLAN, GRIFFINGER & VECCHIONE, 1 RIVERFRONT PLAZA, NEWARK, NJ, 07102-5497, US

(73) Assignee: Science & Technology Corporation @ UNM

(21) Appl. No.: 10/361,215

(22) Filed: Feb. 10, 2003

(51) Int. Cl. H01L 31/00

(52) U.S. Cl. 136/253

(57) ABSTRACT

A radiation power source having a source of radioactive material disposed in at least one hole extending partially through a substrate. A PN junction extends around a predetermined portion of the hole walls. In accordance with one aspect of the present invention, a significant gain in power output is obtained by fabricating the hole so that the ratio of its depth to perimeter is as large as possible. In another embodiment of the present invention, the PN junction surrounding the hole has P and N portions that extend outwardly to opposite sides of the substrate wherein they connect to an associated power . cell lead. This arrangement advantageously simplifies the interconnection of multiple power cells formed on the same substrate.

### TECHNICAL FIELD

This invention relates to power cells for producing electrical energy and, more particularly, to such cells which utilize the radiation emitted by a source material to cause a current to flow in material subjected to this radiation.

### BACKGROUND OF THE INVENTION

Radiation fueled power cells have been contemplated that utilize P-type and N-type semiconductor materials arranged to form a PN junction and a radiation source. The PN junction is disposed so as to receive the radiation emitted by the source. As a result, the electrically-charged particles produced by the decay of the radiation source create electron-hole pairs in the N-type and P-types materials. Such creation results in an associated electrical current flow across the PN junction. As the radiation source can emit such particles for many years and each emitted particle can produce a very large number of electron-hole pairs, radiation fueled power cells have been envisioned as a viable source of electrical energy for certain applications.

These initial visions have been dampened by investigations revealing that the electrical output levels obtained from radiation fueled power cells was insufficient for many commercial applications when feasible radiation sources are used, i.e., sources whose type and level of emitted radiation are acceptable for human exposure. A primary cause for this result is that the design of the power cell did not benefit from much of the emitted radiation. To overcome this problem, a number of different designs were tried. In the main, such designs utilized a horizontal layering of semiconductor materials and radiation sources to provide multiple power cells, each multiple power cell having a PN junction and radiation source. The problem with this approach is that each of the resulting multiple cells had to be electrically connected together, either in series or in parallel, and such interconnection required processing that added undesirable costs to the structure. In addition, the interconnection produced a loss of power so that the resulting power from the interconnected cells was far less than the sum of the power output of each interconnected power cell.

It would therefore by very desirable if a nuclear radiation fuel power cell could be designed using a radiation source compatible with human exposure which meets the power and cost objectives of many commercial applications.

### SUMMARY OF THE INVENTION

Pursuant to the present invention, the shortcomings of the prior art are overcome by recognizing that the output from a nuclear radiation fueled power cell can be significantly enhanced by disposing the radiation source in one or more small, yet deep holes in a substrate. Each hole is surrounded by P-type and N-type semiconductor materials arranged so as to form a PN junction. Defining an aspect ratio as the ratio of the depth of a hole to its perimeter, it has been found that significant gain in the power output of a radiation fueled power cell can be provided by increasing the aspect ratio as much as possible. Indeed, by using an aspect ratio of 10 or more, the power requirements of applications can be met that were not previously attainable with prior art designs. Further, in accordance with the present invention, it is preferably that the PN junction extends around the walls and bottom of each hole.

In another aspect of the present invention, more than one hole is formed in a substrate and prior art interconnection problems can be avoided by forming each type of semiconductor material so as to extend between holes and interconnect to similar type material surrounding each hole. As a result each power cell is interconnected to another. In a disclosed embodiment, a plurality of holes are formed in a substrate and a selected type of semiconductor material surrounds each hole and extend over a first substrate surface. The other type of semiconductor material is in contact with the selected type and extends over a second substrate surface that is opposite to the first substrate surface. Electrical connection to this power cell may be provided by a pair of electrical conductors, each conductor formed so as to connect to the first and second substrate surfaces.

In accordance with another aspect of the present invention, difficulties in fabricating power cells can be avoided by not directly depositing the radiation source materials. Instead, a hydrogen absorbing metal, such as titanium, can be deposited. By then exposing the deposited metal to tritium in a reactor a metallic tritide is formed. Such material is radioactive and emits beta particles. In this technique the radiation emitted by the radioactive material creates electron-hole pairs in N-type and P-type material which is exposed to the radiation. This conversion of a hydrogen absorbing material into a radioactive material source is applicable to a variety of power cell configurations, including those that do not utilize holes but instead deposit radioactive material horizontally on a planar surface or in any of a number of different shaped depressions in a substrate, e.g., a trough.

### BRIEF DESCRIPTION OF THE DRAWINGS

Further objects, features and advantages of the present invention will become apparent from the following written description taken in conjunction with the accompanying figures showing illustrative embodiments of the invention, in which:

FIG. 1 is a top view of a substrate structure including a plurality of holes used in the formation of an illustrative embodiment of a power cell in accordance with the present invention;

FIG. 2 is a front view of FIG. 1

FIG. 3 is a side view of FIG. 1;

FIG. 4 is a front view of an illustrative power cell that uses the structure of FIGS. 1-3; and

FIG. 5 is a front view of another illustrative power cell that uses the structure of FIGS. 1-3.

### DETAILED DESCRIPTION

The present invention is based on a recognition is that the electrical output from a power cell can be substantially enhanced by disposing the radiation source in a small, yet deep hole formed in a substrate and then surrounding this hole with a PN junction. The resulting power cell can be replicated many times on a single substrate and the cells thus formed can be electrically interconnected. This structure has a performance advantage resulting from an increased semiconductor area in contact with the radioactive material.

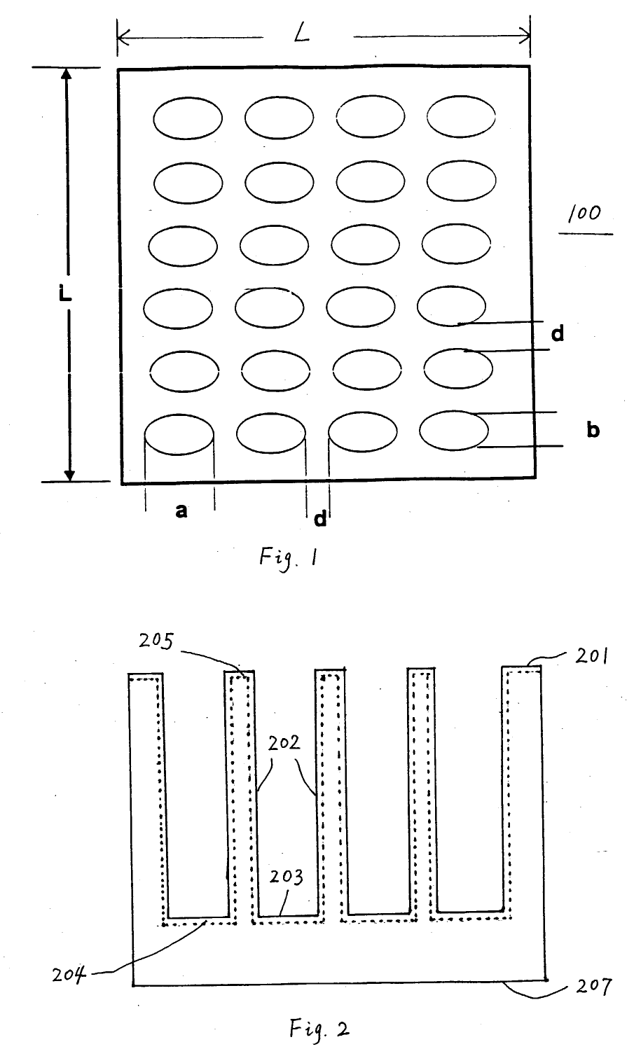

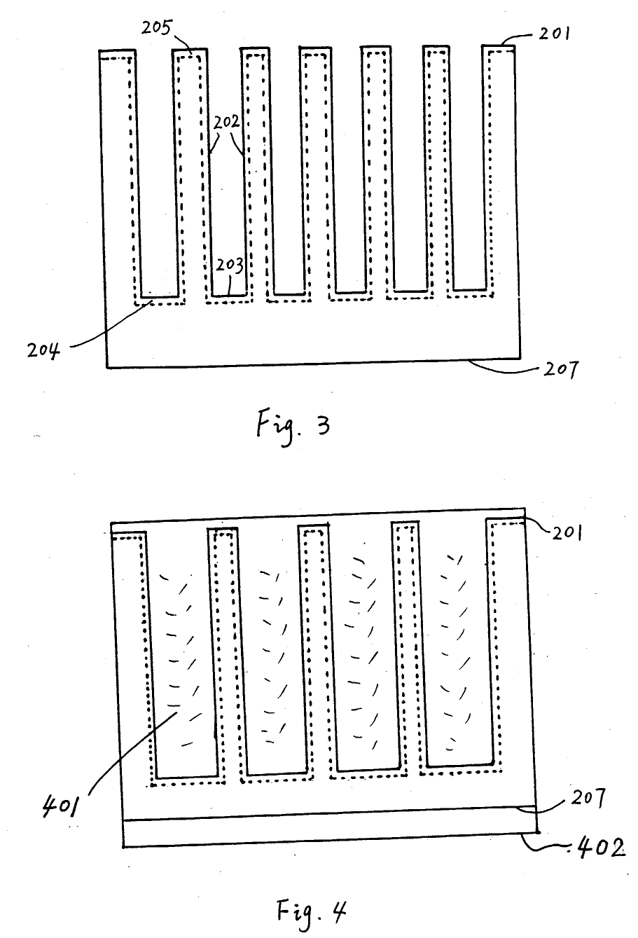

To understand the basis for the benefits of this structure, refer now to FIGS. 1-3 which show an embodiment of the present invention wherein a plurality of holes is formed in a substrate. For illustrative purposes, the substrate is assumed to be N-type semiconductor material. After creation of the holes, by etching or the like, the upper surface 201, the hole side walls 202 and hole bottom 203 are diffusion doped as P-type. It should, of course, be understood that the positions of the P-type and N-type materials in FIGS. 2 and 3 can be interchanged.

The boundary between the P-type and N-type regions is shown in the drawing as a dotted line. Referring to FIGS. 2 and 3, the P-type doping of the side walls and hole bottom produces a P-type region 204 and such doping of the upper surface 201 produces the P-type region 205. Region 204 extends outwardly a predetermined distance from the hole walls 202 and the hole bottom 203. Region 205 downwardly and laterally from surface 201 so as to interconnect the regions 204 surrounding each hole. By depositing radioactive material 206 in each hole, a power cell is produced. Each power cell can be connected to other and/or to other load circuitry through the use of one or more electrical conductors attached to the P-type and to the N-materials.

It should be noted that the N-type material surrounds the P-type material and extends to surface 207. It should be noted that the P-type and N-type materials each extend in one contiguous region on the substrate. This attribute advantageously facilitates the connection of the power cell to other circuitry and avoids power losses in prior art power cell interconnections having multiple and separate PN junctions. For example, by depositing electrically conductive material 207 over each hole and over surface 201 and over surface 207 a pair of leads are provided which interconnect each cell together as well as provide for connection to load circuitry (not shown).

It should be also noted that, as shown in FIGS. 2 and 3, the PN junction advantageously completely surrounds the walls and bottoms of each hole. Such an arrangement maximizes the amount of radiation received by the PN junction and produces a corresponding increase in the number of electron hole-pairs created.

Refer now to FIG. 4. After diffusion doping to form the p-type material, radioactive material 401 is provided into each hole by deposition or the like. While this material may be of the kind that emits α, β, or γ particles, β particle emission is preferable. As shown, this material completely fills each hole to the level of surface 206. Electrical connections are provided by depositing an electrically conductive material 402 and 403 over surfaces 206 and 207, respectively.

Now to understand the advantages of creating deep holes in the above-described power cell structure, refer back to FIG. 1. It is assumed that the dimensions “a” and “b” are the maximum extensions of each hole in the horizontal (“X”) and vertical (“Y”) directions, respectively. The dimension “d” is the distance between holes and it is assumed that this distance is the same in both the X and Y directions. If we now define an aspect ratio (Ω) as the ratio of the depth (“Z”) of each hole to its perimeter (p), the wall area of a single hole, A_{w} can be expressed as

A_{w}=Zp=Ωp² (1)

The number of holes, “N”, in a square substrate with sides “L” is then

N=L²/(d+a)(d+b) (2)

The total PN junction area for the structure of FIG. 1, A_{TV} which includes the bottom of the holes and the top-mesas is

A_{TV}=Ωp²L²/(d+a)(d+b)+L² (3)

In contrast, the total PN junction area of a power cell, A_{TH} formed by layering p-type and n-type material over a substrate having sides L and then layering radioactive material over the top of this layer, is

A_{TV}=L² (4)

We can define the gain, G, or increase in PN junction surface area for the power cell structure of FIG. 1 over that provided by horizontal layering as

G=A_{TV}/A_{TH}=Ωp²/(d+a)(d+b)+1 (5)

The preceding equation assumes that each hole is completely filled with radioactive source material. Assume now that the holes in FIGS. 1-3 were square so that a=b=w and that p=4w. The gain G, assuming each hole filled to substrate surface with radioactive source is

G=16Ωw²/(d+w)²+1 (6)

If, however, the holes are circular with diameter D this area ratio becomes:

G=πD²Ω/(d+D)²+1 (7)

In general, the increased area or improved performance of the power cell becomes some geometric factor times the hole area and aspect ratio divided by the pitch of the holes squared. The pitch is the center-to-center spacing of the holes, i.e., a+d or b+d for oval holes, D+d for round holes and D+w for square holes, etc. Keeping the holes as close packed as possible provides a near cancellation between the square of the pitch and the hole area and the improvement in performance of a cell is a few factors times the aspect ratio of the holes.

The hole dimensions are used to optimize the design of the cell, given a radiation source and practical etching specifications. Preferably, the lateral dimensions should be approximately the range of the emitted particles from the source metal, i.e., α, β, or γ so that most of these particles enter the semiconductor. The depth of the holes provides a significant gain in performance and should be as large as possible. Maximizing the aspect ratio of the hole provides the best results the smallest amount of substrate. With modern etching techniques, aspect ratios of 100:1 or more are possible. Indeed, the high aspect ratios desired by the present invention are routinely employed in the fabrication of memory devices, such as DRAM, and in micromachining technologies. This provides an area gain of some 200 to 400 relative to a flat surface junction. While the substrate may be of a variety of different materials, gallium phosphide appears to be particularly desirable.

Preferably, however, the problems associated with the deposition of radioactive source material can be avoided by depositing a material that is not radioactive but can be processed to become the same. For example, a metal that absorbs hydrogen, such as scandium, titanium, erbium, hafnium and the like can be deposited into each hole and over surface 206. Another electrically conductive material, such as tungsten can be deposited over surface 207. Next an electrically conducting material with a high melting point metal, such as tungsten, is deposited over surface 207. Fabrication of the power cell is now complete with no radioactive material present. The entire cell is then exposed to tritium at elevated temperatures in a tritium reactor where the tritium reacts with the hydrogen absorbing metal to form a metallic tritides. Subsequent beta decay of the tritium provides energy for the cell. Materials other than tungsten may be used which can withstand the temperatures experienced during processing in the tritium reactor.

FIG. 5 shows another embodiment of the present invention which utilizes one or more holes in a substrate. Again, a PN junction is formed around each hole. A radioactive source material is deposited in each hole. The difference between this embodiment and that shown in FIG. 4 is that the p-type material does not extend between holes and each hole is then an independent power cell.

The foregoing description has been presented to enable those skilled in the art to more clearly understand and practice the instant invention. It should not be considered as limitations upon the scope of the invention, but as merely being illustrative and representative of several embodiments of the invention. Numerous modifications and alternative embodiments of the invention will be apparent to those skilled in the art in view of the foregoing description.

What is claimed:

1. A radiation fueled power source comprising:
a substrate of semiconductive material having at least one hole extending partially therethrough, and wherein the ratio of hole depth to hole perimeter is greater than 10;
a radioactive source material in said hole;
a PN junction formed in said substrate surrounding said hole so as to receive radiation emitted by said source;
a first and second power leads respectively connected to said P and N portions of said PN junction.

2. The power source of claim 1 wherein said P and N portions of said PN junction extend to opposite sides of said substrate.

3. The power source of claim 2 wherein said first and second power leads are disposed on the opposite sides of said substrate.

4. The power cell of claim 1 wherein said hole had a circular cross-section.

5. The power cell of claim 1 wherein said hole has an oval cross section.

6. The power cell of claim 1 wherein said hole has a square cross section.

7. The power cell of claim 1 wherein said radioactive source material emits beta rays.

8. The power cell of claim 1 wherein said radioactive material emits gamma radiation.

9. The power cell of claim 1 wherein said radioactive material emits alpha radiation.

10. The power cell of claim 1 wherein a predetermined one of said P and N-type material forming said PN junction is disposed adjacent to the walls of said hole.

11. The power cell of claim 10 wherein a predetermined one of said P and N-type material forming said PN junction is disposed adjacent to the bottom of said hole.

12. The power cell of claim 1 wherein a predetermined one of said P and N-type material forming said PN junction is disposed adjacent to the bottom of said hole.

13. A radiation fueled power source comprising:
a substrate of semiconductive material having at least one hole extending partially therethrough,
a PN junction formed along a predetermined portion of the hole walls, the P and N portions of said PN junction extend to opposite sides of said substrate,
a radioactive source material in said hole;
a first and second power leads disposed on opposite sides of said substrate and respectively connected to said P and N portions of said PN junction.

14. The power cell of claim 13 wherein said hole had a circular cross-section.

15. The power cell of claim 13 wherein said hole has an oval cross section.

16. The power cell of claim 13 wherein said hole has a square cross section.

17. The power cell of claim 13 wherein said radioactive source material emits beta rays.

18. The power cell of claim 13 wherein said radioactive material emits gamma radiation.

19. The power cell of claim 13 wherein said radioactive material emits alpha radiation.

20. The power cell of claim 13 wherein a predetermined one of said P and N-type material forming said PN junction is disposed adjacent to the walls of said hole.

21. The power cell of claim 20 wherein a predetermined one of said P and N-type material forming said PN junction is disposed adjacent to the bottom of said hole.

22. The power cell of claim 13 wherein a predetermined one of said P and N-type material forming said PN junction is disposed adjacent to the bottom of said hole.
